(19) United States
(12) Patent Application Publication
(10) Pub. No.: US 2026/0250830 A1
(43) Pub. Date: Aug. 27, 2026

(54) COATED PLASTIC OR METAL SUBSTRATE AND METHOD FOR PRODUCING A METAL-LOOKING COATING

(71) Applicants: KENOSISTEC S.R.L. (50%), Massa Martana (PG) (IT); BARNEM TECNOLOGIE PLASTICHE S.R.L. (50%), Brescia (IT)

(72) Inventors: Simone Mutti, Massa Martana (PG) (IT); Stefano Perugini, Massa Martana (PG) (IT)

(73) Assignees: KENOSISTEC S.R.L. (50%), Massa Martana (PG) (IT); BARNEM TECNOLOGIE PLASTICHE S.R.L. (50%), Brescia (IT)

(21) Appl. No.: 19/489,695

(22) PCT Filed: Jun. 19, 2024
(86) PCT No.: PCT/IB2024/055975

§ 371 Date: Dec. 3, 2025

(30) Foreign Application Priority Data
Jun. 20, 2023 (IT) 102023000012774

(51) Int. Cl. C23C 14/16; C23C 14/02; C23C 14/06; C23C 14/20; C23C 14/24; C23C 28/00

(52) U.S. Cl. CPC C23C 14/165; C23C 14/024; C23C 14/0635; C23C 14/0641; C23C 14/0664; C23C 14/205; C23C 14/24; C23C 28/32; C23C 28/341

(57) ABSTRACT

Coating (1) for a substrate (100) made of plastic or metal material, comprising at least one first layer (10) made of metal material or metal compound, and at least one second layer (11) made of metal material or metal compound, wherein said first layer (11) is deposited by cathodic sputtering on said substrate (100) and wherein said first layer (11) is made of a material having elasticity modulus of less than 150 Gpa, preferably less than 125 Gpa, and said second layer (12) is deposited by cathodic sputtering on said first layer (10) and wherein said second layer (11) is made of a material or having hardness greater than 600 Vickers.

### TECHNICAL FIELD OF THE INVENTION

Subject-matter of the invention is a substrate made of plastic, or painted plastic or painted metal, and related method for making a coating having chromed appearance.

In particular, the coated substrate and the method are obtained by deposition of a multilayer metal-based coating applied to the components by sputtering technology. In practice, the coating and the related method are used to impart a metal appearance (similar to chrome plating) to plastic components and items, such as, for example, ABS, PCABS and other similar or to painted plastic or painted metals.

### KNOWN PRIOR ART

Metal coatings on plastic articles obtained by chrome-plating galvanic treatment are commonly used in many manufacturing sectors such as the automobile and household appliance industries.

Because of this wide use and current regulations, the need to find alternatives with comparable if not superior functional properties appears to be desirable.

Metal coating of plastic surfaces may also be achieved by other techniques. For example, one of the best-known techniques is the deposition on a substrate by the cathodic sputtering technique.

Such cathodic sputtering technique is used in machines that include, in a known way, a vacuum chamber inside which a substrate to be coated is arranged. The coating of such substrate occurs by the deposition, on its surface, of atoms or ions emitted by a sacrificial solid body subjected to high-energy particle bombardment. In particular, the emission of atoms or ions by the sacrificial body is caused by a plurality of high-energy particles, such as, for example, gas ions in the plasma state, which is caused to strike the sacrificial body, thus also named “target”. In practice, the target undergoes an erosion process. In particular, during the erosion of the target body, the coating material, in the form of atoms, ions, or portions of molecules, detaches from the target body and spreads in the surrounding areas, eventually adhering on the deposition substrate. The erosion of the target body may occur thanks to the use of a strongly ionized gas, in the “plasma” state, interposed between said target body and said deposition substrate and suitably excited to provide high-energy particles intended to strike the target body to cause its erosion mentioned above. Clearly, the metal material that is deposited on the substrate may be pure metal, such as, for example, Chromium or Silver, or a reactive compound thereof. For example, in the case of using Chromium as a target material, the material that will be deposited on the substrate may be, depending on the gas used, either substantially pure Chromium, or Chromium Nitride (CrN), if the strongly ionized gas used is nitrogen, Chromium Carbide (CrC), if the strongly ionized gas used is acetylene or methane, Chromium Oxide (CrO), if the strongly ionized gas used is oxygen, or a combination of Chromium and one of its functional components (depending on the gas selected).

Material deposition machines are known and have an electrical potential difference (for example, a few kV) between the target body and the deposition substrate. Usually, the target body is the cathode (negative pole) whereas the substrate, or the vacuum chamber, is the anode (positive pole).

At the time when an inert gas, such as Argon, is introduced between said target body and said deposition substrate under appropriate pressure conditions (for example, a few mTorr), the free electrons in the gas are accelerated away from the negative charge of the cathode, so that they hit the atoms of the inert gas and ionize them. In this way, a chain reaction is triggered and a strongly ionized gas, or “plasma”, is achieved. The ionized atoms of the inert gas are in this case positively charged atoms and therefore are accelerated by electrical attraction toward the cathode, in this case represented by the target body. The ionized atoms collide with the surface of the target, cause the detachment of coating material (atoms or ions) from the target which, spreading in the direction opposite that occupied by the target, is caused to adhere on the deposition substrate.

Machines for the deposition of material are known and further comprise a plurality of magnets (to form a so called “magnetron”), able to generate a magnetostatic field. Such magnets are usually placed below the target body, or anyway at the latter from the opposite side to that where the substrate to be coated is placed, so that the resulting magnetic field interacts with the ionized atoms in the space interposed between the target body and the deposition substrate, thereby increasing the path to the target body and, therefore, increasing the probability of collisions between the particles. This results in increasing the yield of the process.

Such technique of cathodic sputtering, although it is nowadays widely used in place of galvanic processes, nevertheless proves to be ineffective in the case of plastic supports or painted metal supports since the coating that is obtained, although is aesthetically appreciable and succeeds in preventing moisture from reaching the surface of the substrate, nevertheless does not prevent the occurrence of cracks in the coating that is typically caused by the mechanical and/or thermal expansions that the plastic, or painted metal substrate, undergoes in the course of its normal use. The presence of deep cracks down to the base material gives the plastic component, firstly, an unaesthetic appearance and. secondly, it may compromise the integrity and functionality of the coating, leading to detachment of the coating and thus uncovering of the surface of the material to be coated.

JP2008191528 describes a reflective coating. The coating, deposited by sputtering, is composed of a 50-500 nm-thick first layer of silver or an alloy thereof, and a second 0.5-10 nm-thick SiAlON protective layer. JP2008191528 does not mention any value of elasticity modulus. The coating is suitable for a variety of articles, including light reflectors, electrodes, reflective mirrors, electronic devices, reflectors of a lighting instrument, general lighting articles, back-lighting, LED fixtures, displays and optical discs.

D. Evans et al., Surface and Coatings Technology, Vol. 206(2), pages 312-317, 2011, describes an abrasion-resistant coating. In the experimental section, it is set forth that a support of polymer material is dipped in a hard resin having thickness of 4.6 microns and then coated by sputtering with a layer of SiO₂ having thickness of 140 nm. Subsequently, it is further coated with a 40-50 nm-thick CrNx layer, still by sputtering. SiO₂ is not a metal material and is applied in order to provide abrasion resistance.

JP2015/104924 describes a transparent coating for electronic devices. The coating comprises a first layer made of chromium (underlayer), a second layer (transition layer) made of chromium carbide and a third layer (transparent layer) made of silicon. The thickness of the underlayer ranges from 100 to 300 nm and the thickness of the transition layer from 200 to 400 nm. The layers are deposited by sputtering. Also in this case, silicon is not a metal material and the coating is transparent.

To date, there are no known coatings for plastic or metal materials that allow achieving optimal results in terms of both aesthetics and resistance to surface cracking, with the exception of the coatings obtained by galvanic processes.

### OBJECTS OF THE INVENTION

Object of the present invention is to make a technical coating obtained by cathodic sputtering that is applicable to plastic or painted plastic or painted metal supports, and that is aesthetically identical to that obtainable by galvanic processes existing today.

Further object of the present invention is to make a coating that prevents the occurrence of surface cracks.

Finally, object of the present invention is to develop a method by which the proposed solution may be implemented.

### SUMMARY OF THE INVENTION

The above objects are achieved thanks to a coating for a plastic or metal substrate as defined in the attached claims.

Thus, the first aspect of the present invention is a substrate made of plastic or metal material, provided with a coating, said coating comprising at least one first layer (10) made of metal material or metal compound, at least one second layer (11) made of metal compound and at least one third layer (12) made of metal material or metal compound, wherein:
said first layer is deposited by cathodic sputtering on said substrate and wherein said first layer is made of a material having elasticity modulus of less than 150 Gpa,
said second layer is deposited by cathodic sputtering on said first layer and wherein said second layer is made of a material or having hardness greater than 5.884 GPa (600 Vickers), and
said third layer is deposited by cathodic sputtering on said second layer of a metal material or metal compound having reflectance within the visible spectrum between 55 and 70%.

Preferably, said elasticity modulus of less than 150 Gpa ranges from 4.5 GPa to 150 GPa, preferably from 4.5 GPa to 125 GPa.

Preferably, said hardness above 5.884 GPa (600 Vickers) ranges from 5.884 GPa (600 Vickers) to 60 GPa (6,000 Vickers).

By “metal material” here is meant to denote a pure metal material or a mixture of metal materials, as a dispersion or alloy.

By “metal compound” here is meant to denote a material made of a pure metal material or a mixture of metal materials (as a dispersion or alloy) and one or more non-metal elements (as a dispersion or alloy), said “metal compound” being able to be generated by co-deposition of different materials (metal and non-metal materials) or by a reaction with reactive gases, as will be more extensively described below.

In practice, the first layer deposited on the substrate, thanks to its elasticity, is able to compensate for the different coefficients of thermal expansion and mechanical elongation of the materials involved in the coating process, thus preventing the occurrence of cracks and delaminations inside the entire coating. Considering that the typical coefficient of thermal expansion of a plastic such as, for example, PCABS plastic is in the order of 80×10^{-6 mm}−1K⁻¹, about an order of magnitude higher than that of Chromium, the first “shock-absorbing ” layer is able to totally eliminate the cracks visible to the naked eye (of the entire deposit) and in particular to reduce their density measured under the microscope to values below 0.01 cracks per linear mm after elongation of the plastic substrate by 1% of its size.

It should be clarified that the term plastic is intended to include any polymer that the skilled in the art recognizes as “plastic”, for example, thermoplastic polymers, thermosetting polymers, elastomers, resins, rubbers, etc.

Moreover, such first layer, due to the physical/chemical properties must allow for good adhesion to the surface to be covered, approximately greater than 50 Gpa. This adhesion characteristic also strongly depends on the elastic capability of the material of which the first layer is made.

Ultimately, the first layer performs the function of shock-absorbing layer.

Preferably, the first layer has thickness between 50 and 400 nm.

On the other hand, the second layer imparts abrasion resistance to the entire package, as it must be made using a material that has hardness greater than 600 Vickers. Preferably, said second layer is not made solely of a metal compound.

Preferably, said second layer is not made of SiAlON.

The second layer preferably has thickness greater than 15 nm, preferably greater than 30 nm, more preferably the thickness ranges from 50 to 400 nm.

Furthermore, the coating may preferably comprise a third metal layer deposited by cathodic sputtering on said second layer; said third layer is made of a metal material, or a metal compound, having reflectance within the visible spectrum between 55 and 70%.

Preferably, said third layer comprises at least Chromium.

In practice, the third layer is the “aesthetic” layer. The third layer gives high reflectivity properties to the entire coating. This latter layer is typically chromium-based to give the part the typical chromed appearance similar to that produced in the galvanic industry.

According to an embodiment, said third layer may also comprise additional agents selected from, for example, dopants, dyes, antibacterials and mixtures thereof.

Still, the coating may preferably comprise an additional painting layer arranged between said substrate and said first metal layer; said painting layer being made of paint selected from thermal paint and UV paint. Such painting layer is essential in the case of plastic substrate.

According to the proposed solution, said first layer and/or said second layer is/are made of a substantially pure metal material and/or its reactive compounds, wherein said pure metal material is selected from Chromium, Silver, Copper and Indium and said reactive compounds are obtainable by means of a gas selected from Argon, Oxygen, Nitrogen, Methane and Acetylene and mixtures thereof such as, for example, argon and methane, argon and acetylene, nitrogen and methane.

According to a particular solution, said first layer and/or said second layer and/or said third layer is/are made of a material comprising Chromium and/or Chromium Nitride and/or Chromium Carbide and/or Chromium Oxide and/or Chromium Carbonitride, provided that
said first layer is not constituted by Chromium only;
said second layer is not constituted by a metal compound only;
preferably, said third layer comprises at least Chromium.

According to a particular aspect, said first layer preferably comprises Chromium Carbide or Chromium Carbonitride.

In accordance with a particular embodiment, said second layer preferably comprises Chromium Nitride.

According to a particular embodiment, the metal material, or metal compound, selected as first layer and second layer could also be identical, but provided that the first layer has elasticity modulus of less than 150 Gpa, preferably less than 125 Gpa, and the second layer has hardness greater than 600 Vickers.

However, it should be specified that both the first layer and the second layer could be obtained by the deposition of a plurality of metal layers which, however, must give the first layer and the second layer the mechanical properties of elasticity and hardness as a whole, respectively, required by the invention to achieve the desired technical effects.

The first layer, for example, may comprise a first portion of Chromium layer, for greater adhesion to the substrate, and then—above that first portion of the layer—a second portion of a Chromium Carbonitride layer, in which the greater amount of Chromium Carbonitride gives the first layer overall better elastic properties than those of Chromium only, i.e., a lower elasticity modulus of Chromium (thus greater elasticity).

The third layer is preferably made of Chromium, however other materials or reactive compounds could also be used, as long as the reflectance within the visible spectrum is between 55 and 70%.

The objects are also achieved by a method for making a coating on a substrate made of plastic or metal material according to one or more of the attached claims, by means of an apparatus for deposition by cathodic sputtering, wherein said apparatus comprises at least one vacuum chamber, at least one evaporator device for a target body and at least one support for said substrate, said evaporator device and said support being arranged inside said vacuum chamber, said method comprising the steps of:
a) arranging a substrate made of metal or plastic material on said support;
b) depositing, by cathodic sputtering on said substrate, a first metal layer or metal compound;
c) depositing, by cathodic sputtering on said first metal layer, a second layer of a metal compound;
   wherein said first metal layer is made of a metal material or metal compound having elasticity modulus of less than 150 Gpa, preferably less than 125 Gpa, and wherein said second layer is made of a metal compound having hardness greater than 600 Vickers.

The ranges of elasticity modulus and hardness exemplified above also apply to the method of the invention.

Still, prior to said step a), the step of painting said substrate by paint selected from thermal paint and UV paint is included.

Furthermore, the method also comprises the step d) of depositing on said second layer, by cathodic sputtering, a third metal layer or metal compound, wherein said third layer is made of a metal material, or metal compound, having reflectance within the visible spectrum between 55 and 70%. Said third layer preferably comprises Chromium.

Said step b), or said step c), or said step d), occurs by using an ionized and properly excited gas selected from Argon, Oxygen, Nitrogen, Methane, Acetylene and mixtures thereof as a carrier gas.

Finally, said target body is selected from Chromium, Silver, Copper and Indium.

In practice, by means of one or more of the above-mentioned ionized gases and one or more target bodies, it is possible to obtain a first layer, a second layer and a third layer made of a metal material, or metal compound, selected from Chromium, Silver, Copper and Indium and/or its reactive compounds obtained with Oxygen, Nitrogen, Methane, Acetylene and mixtures thereof.

### BRIEF DESCRIPTION OF THE FIGURES

Reference will be made to the figures in the attached drawings, in which:

FIG. 1 shows the cross section of a cathodic sputtering machine;

FIG. 2 shows the cross section of a substrate coated by using the machine in FIG. 1;

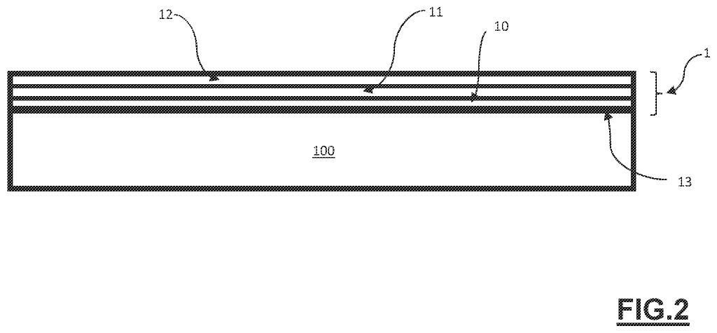

FIGS. 3a, 3b and 3c show images under a 50X microscope of three T85XF plates with UV-type paint after treatment for 5 hours in an oven at 70/80° C. (not according to the invention), each with a distinct coating;

FIGS. 4d, 4e and 4f show images under a 50X microscope of three T85XF plates with glass fiber with UV-type paint after treatment for 5 hours in an oven at 70/80° C. (not according to the invention), each with a distinct coating;

FIGS. 5g, 5h and 5i show additional images under a 50X microscope of three T85XF plates with UV-type paint after treatment for 5 hours in an oven at 70/80° C. (not according to the invention), each with a distinct coating;

FIG. 6a′, 6b′ and 6c′ show images under a 50X microscope of three T85XF plates with UV-type paint after treatment for 5 hours in an oven at 70/80° C. (according to the invention), each with a distinct coating;

FIG. 7d′, 7e′ and 7f′ show images under a 50X microscope of three T85XF plates with glass fiber with UV-type paint after treatment for 5 hours in an oven at 70/80° C. (according to the invention), each with a distinct coating.

### DETAILED DESCRIPTION OF PREFERRED EMBODIMENTS

Various embodiments and variants of the invention will be described hereunder, and this with reference to the figures set forth above. In particular, the coating according to the invention is referred to as 1.

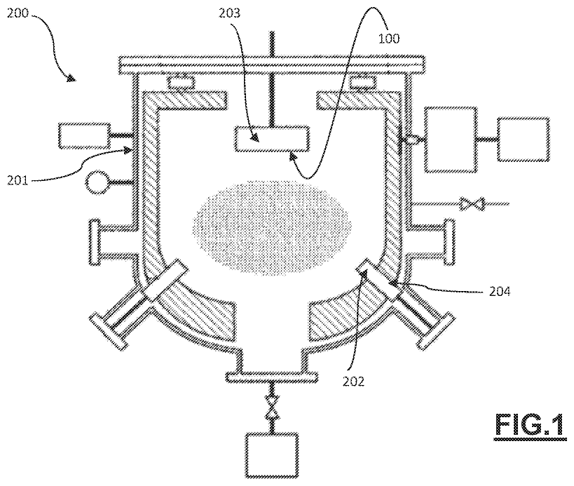

In FIG. 1, an apparatus 200 for obtaining a coating 1 of a plastic or metal substrate 100 according to the invention is shown.

Such apparatus 200 comprises, in a highly synthetic manner, a vacuum chamber 201 inside which the substrate 100 to be coated is arranged. The coating 1 of such substrate occurs by the deposition, on its surface, of atoms or ions emitted by a sacrificial solid body, or target, 202 subjected to high-energy particle bombardment. The sacrificial body 202 is placed inside an evaporation device 204 arranged to supply vapor-phase evaporation material of the solid sacrificial body. In particular, the emission of atoms or ions by the sacrificial body 202 is caused by a plurality of high-energy particles, such as, for example, gas ions in the plasma state, which is caused to strike the sacrificial body 202. In practice, the sacrificial body 202 undergoes an erosion process. In particular, during the erosion of the sacrificial body 202, the sacrificial body 202, in the form of atoms, ions or portions of molecules, detaches from the sacrificial body and spreads in the surrounding areas, eventually going to adhere on the deposition substrate 100 that is held on a support 203 of the substrate 100. The erosion of the target body 202 may occur thanks to the use of a strongly ionized gas, in the “plasma” state, interposed between the sacrificial body 202 and the substrate 100 and suitably excited to provide high-energy particles intended to strike the sacrificial body 202 to cause its erosion mentioned above. Clearly, the metal material that is deposited on the substrate 100 may be pure metal, such as, for example, Chromium or Silver, or a functional component thereof. For example, in the case of using Chromium as a sacrificial body 202, or target, the material that will be deposited on the substrate may be, depending on the gas used, either substantially pure Chromium or Chromium Nitride (CrN), if the strongly ionized gas used is Nitrogen, Chromium Carbide (CrC), if the strongly ionized gas used is acetylene or methane, Chromium Oxide (CrO), if the strongly ionized gas used is oxygen, Chromium Carbonitride (CrCN), if the strongly ionized gas used is a mixture of methane and nitrogen or a combination of Chromium and one of its functional components (depending on the gas selected).

It should be pointed out that the brute formulas set forth above are purely indicative of the elements that make up the layers and include all possible compounds/complexes that may be formed with the elements specified in these brute formulas.

When the first layer comprises a first portion of substantially pure Chromium layer, then said first layer must comprise an additional portion that is not only constituted by pure Chromium in order to meet the values of the elasticity modulus defined here, as will be described in detail hereinbelow.

The growth of the coating 1 then depends on many factors in addition to the target material 202 and the ionized gas, including the pressure inside the vacuum chamber 201, the flow rate of the ionized gas, the intensity and shape of the magnetostatic field generated inside the vacuum chamber 201, at the target body 202, and many other factors. Therefore, it is possible to obtain coating layers that although being composed of the same material have distinct mechanical properties because they depend on the concentration of encapsulated gas within the same layer deposited on the substrate 100.

According to the embodiment described here, the substrate 100 is made of plastic material, however in another embodiment such substrate 100 to be coated may also be made of metal.

The coating 1 comprises a first layer 10 of metal material or metal compound and a second layer of metal material 11 or metal compound. The first layer is deposited by cathodic sputtering on the substrate 100 and has elasticity modulus (or Young's Modulus) of less than 125 Gpa. In any case, a first layer 10 that had elasticity modulus of less than 150 Gpa would still fall within the scope of protection of the present invention.

The second layer 11 is deposited by cathodic sputtering on the first layer 10 and is made of a metal compound having hardness greater than 600 Vickers.

According to the embodiment described here, the first layer 10 has thickness of 150 nm, however, in another embodiment such first layer 10 may have thickness between 50 and 400 nm, without thereby falling outside the scope of protection of the present invention.

The second layer 11 has thickness of 200 nm, however in another embodiment such second layer 11 may have thickness between 50 and 400 nm, without thereby falling outside the scope of protection of the present invention.

Again, the coating 1 comprises a third metal layer 12 deposited by cathodic sputtering on the second layer 11. Such third layer 12 is made of a metal material, or a metal compound, having reflectance within the visible spectrum between 55 and 70% and comprising Chromium.

In practice, for each deposited layer 10, 11, and 12 the metal material or metal compound has mechanical and/or physical properties that allow the coating 1 itself to prevent cracking.

As a matter of fact, the first layer has the function of cushioning or shock-absorbing layer, between the substrate 100 and the second layer 11. Such first layer 10, thanks to the elastic properties of the material is composed of, is able to compensate for the different coefficients of thermal expansion and mechanical elongation of the materials involved in the process, thus preventing the occurrence of cracks and delaminations inside the entire coating.

The second layer 11, the “hardening” layer, on the other hand, imparts hardness to the coating, thus ensuring high abrasion resistance.

Finally, the third layer 12 is the aesthetic layer, i.e., it is used to give the substrate to be coated the finish desired by the end user, which will need to be similar to that obtainable by the galvanization processes of the known art.

According to the embodiment described here, the coating 1 comprises an additional painting layer 13 arranged between the substrate 100 and the first layer 10. Such a painting layer 13 is made with paint selected from thermal paint and UV paint. In the case of the embodiment described here, such paint is of the UV type. In practice, before the substrate 100 is coated by cathodic sputtering inside the apparatus 200, it is painted with such a layer of paint 13.

Preferred Chromium metal compounds are selected from Chromium Nitride (CrN), Chromium Carbide (CrC), Chromium Oxide (CrO), Chromium Carbonitride (CrCN) or a combination of Chromium and its metal compounds such as Chromium Nitride (CrN), Chromium Carbide (CrC), Chromium Oxide (CrO) and Chromium Carbonitride (CrCN).

In particular, in the embodiment described here, the first layer 10 comprises Chromium Carbide with high carbon content such that its elasticity modulus is less than 125 GPa. In particular, Chromium Carbide of the first layer 10 is made such that its elasticity modulus is 90 Gpa.

As a matter of fact, it has been experimentally observed that the elasticity modulus of Chromium Carbide varies strongly depending on the carbon content available in the ionized gas mixture used. If such carbon is in high amounts and the target material used is Chromium, then almost all of the material eroded from the sacrificial body binds to the Carbon and forms Chromium Carbide, while the remaining part that no longer finds Carbon available is deposited on the substrate as Chromium. Under Carbon-saturated conditions, all of the Chromium binds with it so that the entire first layer is constituted by Chromium Carbide.

However, it should be mentioned that in some cases some of the available Carbon remains trapped in the material of which the first layer 10 is composed, also contributing to changes in the elasticity of the first layer 10. In this case, the first layer 10 may include Chromium Carbide (CrC), Chromium and Carbon, or Chromium Carbide (CrC) and Carbon. The brute formula of Chromium Carbide (CrC) mentioned above is purely indicative and includes all possible compounds/complexes that may be formed with the elements specified in that brute formula. In particular, in the case where the apparatus 200 works in an acetylene/methane environment, the compound that is created could have not only Chromium Carbide (CrC) and Chromium, but also a percentage of a-C:H and/or a-C, i.e., Amorphous Carbon molecules in graphite- or Diamond-Like form.

Another material particularly suitable for the first layer 10 comprises Chromium Carbonitride, as will also be evident from the experimental examples below.

Furthermore, the Proprietor experienced that the first layer 10, for example, may comprise a first portion of Chromium layer, for greater adhesion to the substrate, and then—above that first portion of layer—a second portion of Chromium Carbonitride or Chromium Carbide layer, in which the greater amount of Chromium Carbonitride, or Chromium Carbide, gives the first layer overall better elastic properties than those of Chromium only, i.e., a lower elasticity modulus of Chromium (thus greater elasticity). The first Chromium portion is deposited on the preferably painted substrate 100, while the second Chromium Carbonitride or Chromium Carbide portion is deposited on said first Chromium portion.

According to an embodiment, the first layer (10) comprises Chromium Carbonitride and/or Chromium Carbide.

According to an embodiment, the first layer 10 is made of Chromium and Chromium Carbonitride and/or Chromium Carbide.

In any case, whatever the material of which the first layer is made, a first Chromium portion may always be deposited to ensure better adhesion of the first layer to the substrate 100. The second portion of the first layer may be made of a material such that the elasticity modulus of the first layer is overall less than 150 Gpa, preferably less than 125 Gpa.

Again, the second layer 12 preferably comprises Chromium Nitride.

In accordance with a particular embodiment, the first layer 10 and the second layer 11 could also be made predominantly of Chromium Carbide (or Chromium Nitride or other reactive Chromium compound), however, depending on the carbon concentration of the ionized gas used in the apparatus 200, it is possible to vary the mechanical properties of the layer to be made and have a more elastic material or one with greater hardness. If, for example, the concentration of Carbon ions in the plasma is high (deriving from strongly ionized methane or acetylene), the Chromium that detaches from the sacrificial body will bond to the Carbon to form Chromium Carbide, but if that concentration of Carbon is not such that it saturates the environment, then some of the Chromium from the sacrificial body will be deposited as simple Chromium. This final compound, which the first layer is composed of, will vary the mechanical properties depending on the desired concentration of Chromium and Chromium Carbide, resulting in a more elastic or harder material. Changes in the composition of the first layer may be obtained by conveniently using the apparatus 200.

The above example may also be extended in cases where other reactive components of Chromium are used or another pure material is used as a sacrificial body (e.g.: Copper or Silver or Indium) and their respective reactive compounds. In the case of Copper and Silver, since the elasticity modulus of these materials is less than 150 Gpa, then the first layer 10 could be made entirely of these materials. In this case, it is possible to provide the use of a first portion of Chromium layer deposited on the substrate and a second portion of Copper or Indium or Silver layer.

The third layer 13 is preferably made of Chromium.

The coating 1 of the substrate 100 may be made by means of a deposition apparatus 200 by cathodic sputtering of the type illustrated above and shown in FIG. 1, i.e., comprising a vacuum chamber 210, one or more evaporator devices 204 for a target (or sacrificial) body 202, and a support 203 for the substrate 100, in which the evaporator devices 204 and the support 203 are arranged inside the vacuum chamber 201.

As will be described in detail in the experimental section that follows, the method of the invention using the apparatus 200 allows a homogeneous and crack-free coating to be achieved, even after an oven treatment, contrary to the methods of the prior art.

The method for making the coating by such apparatus 200 comprises the steps of:
a) preparing the substrate 100 on the support 203, arranged inside the vacuum chamber 201 of the apparatus 200;
b) depositing, by cathodic sputtering on the substrate 100, a first layer 10 as defined here;
c) depositing, by cathodic sputtering on the first layer 10, a second layer 11 as defined here;
   wherein the first layer 10 is made of a material having elasticity modulus of less than 150 Gpa, preferably less than 125 Gpa, and wherein the second layer 11 is made of a material having hardness greater than 600 Vickers.

Furthermore, prior to step a), a step of painting the substrate 100 by paint selected from thermal paint and UV paint, may be included. In the embodiment described here, the paint is of thermal type. Note that in another embodiment such substrate 100 can also be made of painted metal.

Again, the method also comprises step d) of depositing a third metal layer 12 on the second layer 11 by cathodic sputtering. Such third layer 12 is made of a metal material, or a metal compound, having reflectance within the visible spectrum between 55 and 70% and comprising at least Chromium. In the embodiment described here such metal material, or such metal compound, has reflectance in the visible spectrum of 60%.

Furthermore, said step b) or said step c) or said step d) occurs by using an ionized and properly excited gas selected from Argon or Oxygen or Nitrogen or Methane or Acetylene, as a carrier gas, optionally in the presence of Argon.

Finally, the target body 202 is selected from Chromium, Silver, Copper and Indium.

In this way, depending on the selected gas, the first layer 10 and/or the second layer 11 and/or the third layer 12 can be made of a metal material selected from Chromium, Silver, Copper and Indium and/or its reactive compounds, as defined here.

In particular, if the target body is Chromium, then the first layer 10 and/or the second layer and/or the third layer 12 is/are made of a material selected from Chromium, Chromium Nitride (CrN), Chromium Carbide (CrC), Chromium Oxide (CrO) and a combination thereof, provided that the conditions defined above are met.

The first layer 10 is preferably made of Chromium Carbonitride or Chromium Carbide.

The second layer 11 is preferably made of Chromium Nitride.

Finally, the third layer 12 is preferably made of Chromium.

The invention will be described in detail in the Experimental section below, by way of illustration only and in no way limiting.

### EXPERIMENTAL SECTION

### Example 1

T85XF plaques (or substrates), with or without fiberglass, were coated by deposition of a single- or multi-layer metal-based coating by “sputtering” technology. Such plates or substrates were previously painted with UV-type paint and left to dry for about 60 s.

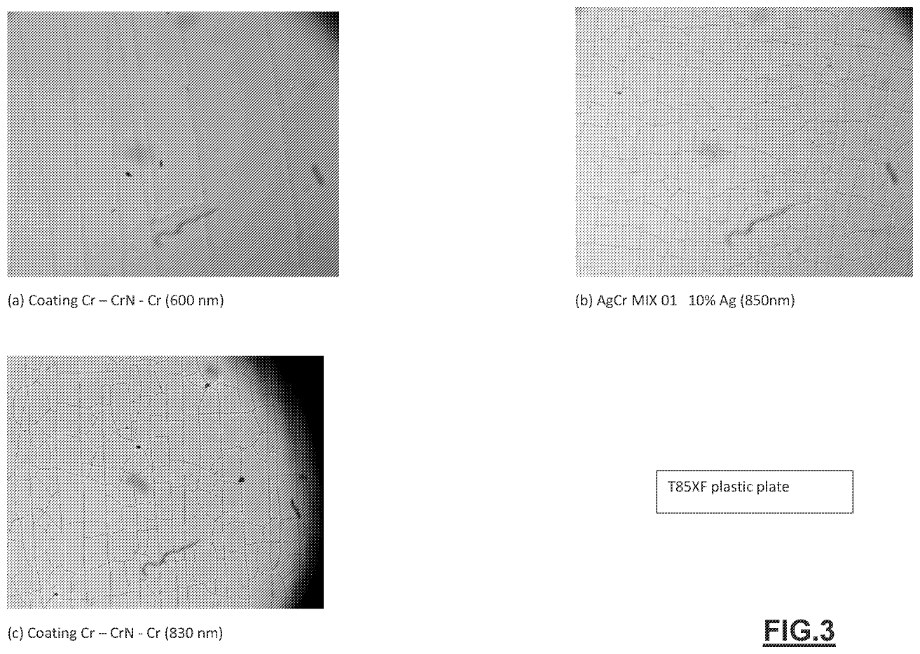

FIGS. 3 to 7 show the images under a 50X microscope after treatment for 5 hours at 70/80° C. of the samples coated according to the invention or comparative samples.

### Comparative Examples

FIG. 3 shows the result of the treatment of a T85XF plastic plate, not according to the invention coated with (a) Cr—CrN—Cr (coating with total thickness of 600 nm), (b) AgCr MIX with 10% Ag (coating with total thickness of 850 nm) and (c) Cr—CrN—Cr (coating with total thickness of 830 nm).

All samples had cracks visible even to the naked eye at the end of the treatment.

It should be noted that a multilayer coating, thus having more than one layer, as in the above-mentioned case of Cr—CrN—Cr coating, has to be read, from left to right, as a coating that has Chromium as the first layer, Chromium Nitride as the second layer and Chromium as the third layer.

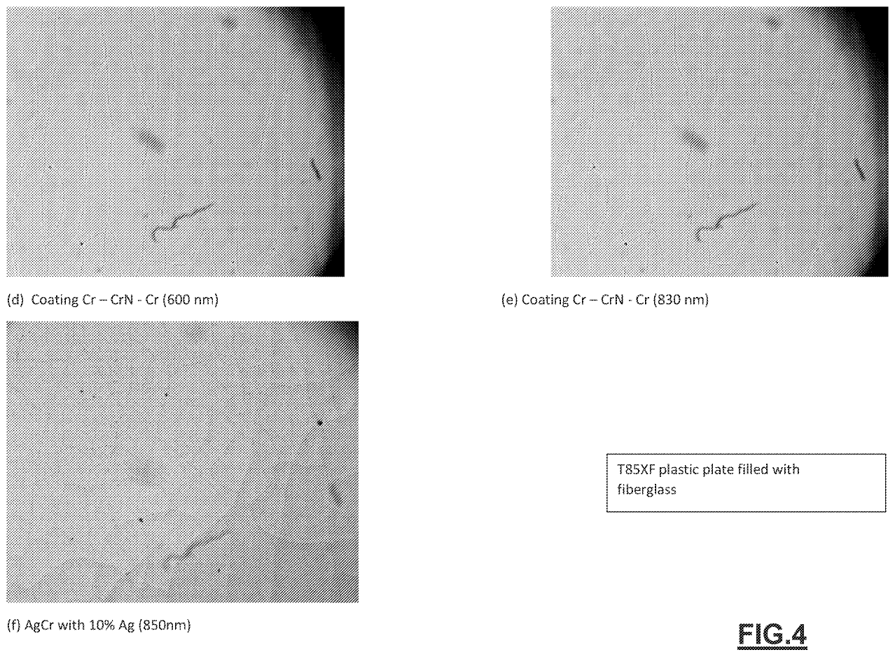

FIG. 4 shows the result of the treatment of a T85XF plate with fiberglass, not according to the invention coated with (d) Cr—CrN—Cr (coating with total thickness of 600 nm), (e) Cr—CrN—Cr (coating with total thickness of 830 nm) and (f) AgCr with 10% Ag (coating with total thickness of 850 nm).

All samples had cracks, which were visible even to the naked eye after the oven treatment.

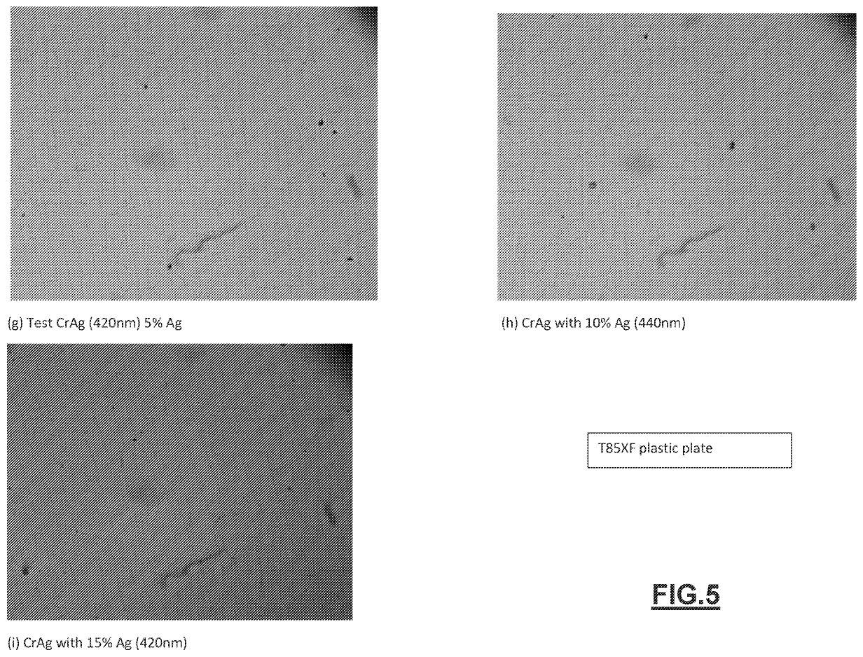

FIG. 5 shows the result of the treatment of a T85XF plate, not according to the invention coated with (g) CrAg single-layer with 5% Ag (coating with overall thickness of 420 nm), (h) CrAg single-layer with 10% Ag (coating with thickness of 440 nm), (i) test CrAg single-layer with 15% Ag (coating with overall thickness of 420 nm).

All samples had cracks, which were visible even to the naked eye.

In practice, in the above examples, the first layer has elasticity modulus that is always above the value of 150 Gpa, as claimed.

### Examples According to the Invention

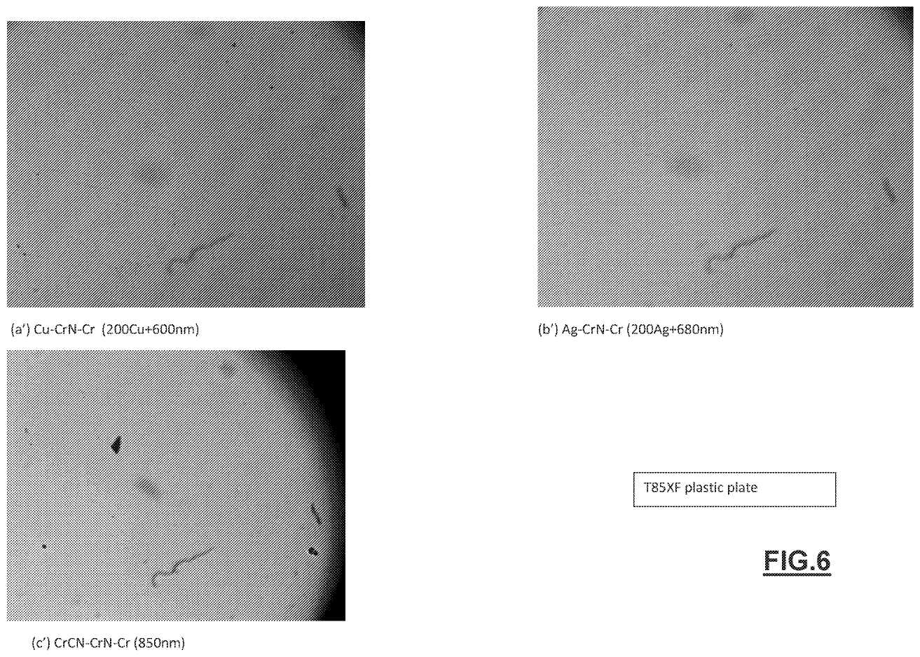

FIG. 6 shows the result of the treatment of a T85XF plate, according to the invention coated with (a′) Cu—CrN—Cr (coating with 200 nm thickness of Cu and 600 nm thickness of the remaining two layers), (b′) Ag—CrN—Cr (coating with 200 nm thickness of Ag and 680 nm thickness of the remaining two layers) and (c′) CrCN—CrN—Cr (coating with overall thickness of 850 nm).

Such plates had a first layer comprising a very thin first portion of Chromium layer and a second portion of Carbonitride layer.

The thickness of such first portion is a few tens of nanometers.

All samples had no cracks visible to the naked eye after the oven treatment. The samples (a′) and (b′) showed cracks visible only under the microscope. The sample (c′) had no cracks visible under the microscope.

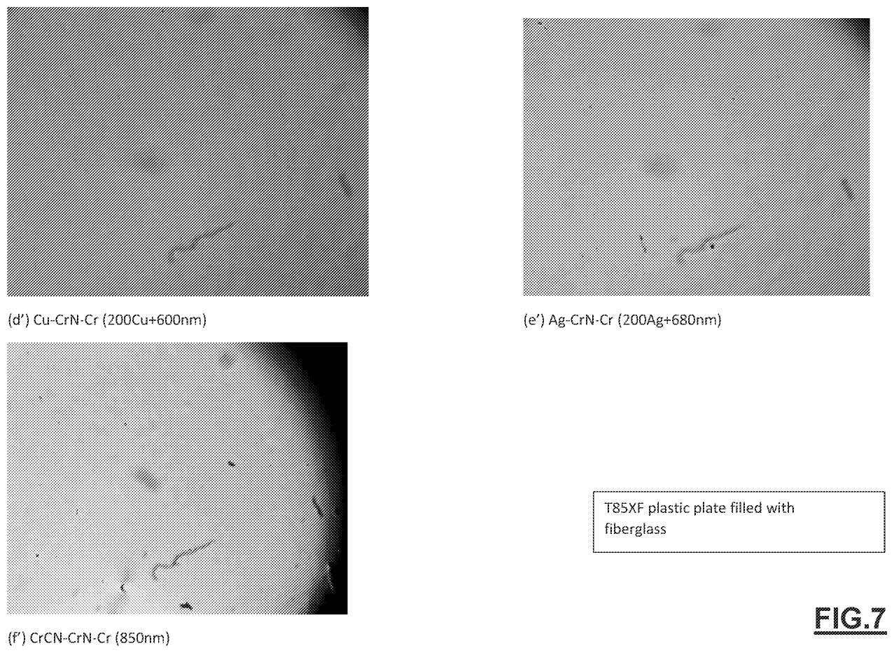

FIG. 7 shows the result of the treatment of a T85XF plate with fiberglass, according to the invention coated with (d′) Cu—CrN—Cr (coating with 200 thickness of Cu for the first layer and 600 nm thickness of the following two layers), (e′) Ag—CrN—Cr (coating with 200 thickness of Ag for the first layer and 680 thickness of the additional two layers) e (f′) CrCN—CrN—Cr 01 (coating with overall thickness of 850 nm).

All samples had no cracks visible to the naked eye before or after the oven treatment. The samples (d′) and (e′) showed cracks visible only under the microscope. The sample (f′) had no cracks.

### Conclusions

By comparing the results obtained for the samples treated according to the method of the invention and for the comparative samples, it is evident that the method of the invention provides better results by preventing the occurrence of cracks on the coatings. In some cases, cracks are visible only under the microscope, however, the result is still acceptable since the important aspect is that these cracks are not visible to the naked eye.

1. Substrate (100) made of plastic or metal material, provided with a coating (1), said coating (1) comprising at least one first layer (10) made of metal material or metal compound, at least one second layer (11) made of metal compound and at least one third layer (12) made of metal material or metal compound, wherein:
said first layer (10) is deposited by cathodic sputtering on said substrate (100) and wherein said first layer (10) is made of a material having elasticity modulus of less than 150 Gpa,
said second layer (11) is deposited by cathodic sputtering on said first layer (10) and wherein said second layer (11) is made of a material having hardness greater than 5.884 GPa (600 Vickers), and
said third layer (12) is deposited by cathodic sputtering on said second layer (11) of a metal material or metal compound having reflectance within the visible spectrum between 55 and 70%.

2. Substrate according to claim 1, wherein said first layer has thickness between 50 and 400 nm.

3. Substrate according to claim 1 or 2, wherein said first layer (10) has elasticity modulus of less than 125 Gpa.

4. Substrate according to one or more of claims 1 to 3, comprising an additional painting layer (13) arranged between said substrate and said first metal layer, said painting layer being made of paint selected from thermal paint and UV paint.

5. Substrate according to one or more of claims 1 to 4, wherein said metal material is selected from Chromium, Silver, Copper and Indium and said metal compound is obtainable by means of a gas selected from Oxygen, Nitrogen, Methane, Acetylene and mixtures thereof, optionally in the presence of Argon,
provided that said first layer is not made of Chromium only.

6. Substrate according to one or more of claims 1 to 5, wherein said first layer (10) and/or said second layer (11) and/or said third layer (12) is/are made of a material comprising Chromium and/or Chromium Nitride (CrN) and/or Chromium Carbide (CrC) and/or Chromium Oxide (CrO) and/or Chromium Carbonitride (CrCN), provided that said first layer (10) is not made of Chromium only.

7. Substrate according to claim 6, characterized in that the first layer (10) comprises Chromium Carbonitride (CrCN) or Chromium Carbide (CrC).

8. Substrate according to claim 6 or 7, characterized in that said first layer (10) comprises a first portion of Chromium layer deposited on said substrate (100) and a second portion of Chromium Carbonitride, or Chromium Carbide, layer deposited on said first portion of Chromium layer.

9. Substrate according to one or more of claims 6 to 8, characterized in that the second layer (11) comprises Chromium Nitride.

10. Substrate according to one or more of claims 6 to 9, characterized in that said third layer (12) comprises Chromium, preferably consists of Chromium.

11. Substrate according to one or more of claims 1 to 10, characterized in that said third layer (12) also comprises agents selected from dopants, dyes, antibacterials and mixtures thereof.

12. Substrate according to any one of claims 1 to 11, characterized in that said first layer (10) comprises Chromium Carbonitride or Chromium Carbide; said second layer (11) is made of Chromium Nitride; and said third layer (12) is made of Chromium, optionally supplemented with agents selected from dopants, dyes, antibacterials and mixtures thereof.

13. Method for making a coating on a substrate (100) made of plastic or metal material according to one or more of claims 1 to 12, by means of an apparatus (200) for deposition by cathodic sputtering, wherein said apparatus (200) comprises at least one vacuum chamber (210), at least one evaporator device (204) for a target body (202) and at least one support (203) for said substrate (100), said at least one evaporator device (204) and said support (203) being arranged inside said vacuum chamber (201), said method comprising the steps of:
a) arranging a substrate (100) made of painted plastic or metal material on said support (203);
b) deposing, by cathodic sputtering on said substrate, a first layer (10) as defined in any one of claims 1 to 12;
c) deposing, by cathodic sputtering on said first layer (10), a second layer (11) as defined in any one of claims 1 to 12; and
d) deposing, by cathodic sputtering on said second layer (11), a third layer (12) as defined in any one of claims 1 to 12,
wherein said first layer (10) is made of a material having elasticity modulus of less than 150 Gpa, preferably of less than 125 Gpa,
wherein said second layer (11) is made of a material having hardness greater than 5.884 Mpa (600 Vickers), and
wherein said third layer (12) is made of a material having reflectance within the visible spectrum between 55 and 70%.

14. Method according to claim 13, wherein, prior to said step a), the step of painting said substrate by paint selected from thermal paint and UV paint is included.

15. Method according to one or more of claims 12 to 14, wherein said step b), or said step c), or said step d), occurs by employing as a carrier gas an ionized and properly excited gas selected from Oxygen, Nitrogen, Methane, Acetylene and mixtures thereof, optionally in the presence of Argon.

16. Method according to one or more of claims 12 to 15, wherein said target body (20) is selected from Chromium, Silver, Copper and Indium.

17. Use of a coating as defined in any one of claims 1 to 12, to provide a chromed appearance free of surface cracks to a painted plastic or metal support.
